(19) United States
(12) Patent Application Publication
(10) Pub. No.: US 2026/0344459 A1
(43) Pub. Date: Oct. 29, 2026

(54) PACKAGE STRUCTURE

(71) Applicant: Advanced Semiconductor Engineering, Inc., Kaohsiung (TW)

(72) Inventors: Chao-Hung WENG, Kaohsiung (TW); Chia-Hao SUNG, Kaohsiung (TW); Ping-Feng YANG, Kaohsiung (TW)

(73) Assignee: Advanced Semiconductor Engineering, Inc., Kaohsiung (TW)

(21) Appl. No.: 19/190,506

(22) Filed: Apr. 25, 2025

(51) Int. Cl. H10W 70/60; H10W 70/695; H10W 74/10; H10W 90/00

(52) U.S. Cl. CPC H10W 70/611; H10W 70/695; H10W 90/00; H10W 90/401; H10W 70/60; H10W 74/111

(57) ABSTRACT

The present disclosure relates to a package structure. The package structure includes a circuit structure having a first surface and a molded interposer disposed on the first surface of the circuit structure. The molded interposer includes a first pin and a second pin. The first pin is tilted in a first direction with respect to the first surface in a cross-sectional view, and the second pin is tilted in a second direction with respect to the first surface in the cross-sectional view. The second direction is different from the first direction.

### BACKGROUND

### 1. Technical Field

The present disclosure relates generally to a package structure, and more particularly to a semiconductor package structure utilizing interposers integrating multiple conductive pins.

### 2. Description of the Related Art

In packaging process (such as, panels), the formation of vertical communication typically relies on plating during photolithography to create conductive pillars. However, this process faces several challenges, particularly in terms of plating uniformity. Factors such as the current amount, duration, plating solution concentration, and total plating area during plating process for manufacturing metal pillars can affect the plating quality, leading to uneven pillar height. In some cases, pillars at the corners of the panel tend to be taller, resulting in significant height differences across the panel, which increases grinding time to make them having the same height. Additionally, after plating, the metal pillars exhibit uneven width (e.g., wider at the top and narrower at the bottom), which makes it difficult to meet the requirements for small pitch at a certain height. Furthermore, excessively long plating times can impact overall process efficiency. Therefore, an improved package structure is called for.

### SUMMARY

In some embodiments, a package structure includes a circuit structure having a first surface and a molded interposer disposed on the first surface of the circuit structure. The molded interposer includes a first pin and a second pin. The first pin is tilted in a first direction with respect to the first surface in a cross-sectional view, and the second pin is tilted in a second direction with respect to the first surface in the cross-sectional view. The second direction is different from the first direction.

In some embodiments, a package structure includes a first pin and a redistribution layer (RDL). The first pin is encapsulated by a first encapsulant and has a top surface in an elliptical shape. The RDL is disposed on the first pin, and includes a first conductive via and a dielectric layer partially covering the first conductive via. The first conductive via is disposed on the first pin and contacts the top surface of the first pin. The conductive via exposes a portion of the top surface of the first pin.

In some embodiments, a package structure includes a first redistribution layer (RDL), a second redistribution layer (RDL), an interposer, and an encapsulant. The first RDL includes a first dielectric layer and a first conductive via partially covered by the first dielectric layer. The second RDL (50) includes a second dielectric layer and a second conductive via partially covered by the second dielectric layer. The interposer is disposed between the first RDL and the second RDL, and includes a first pin. The encapsulant encapsulates the interposer and has a top surface and a bottom surface opposite to the top surface. A top surface of the first pin is substantially aligned with the top surface of the encapsulant, and a bottom surface of the first pin is substantially aligned with the bottom surface of the encapsulant. The first conductive via and the second conductive via taper toward the interposer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure, in accordance with some embodiments of the present disclosure.

FIG. 2A is an enlarged view of region “2A” in FIG. 1, in accordance with some embodiments of the present disclosure.

FIG. 2B is an enlarged view of region “2B” in FIG. 1, in accordance with some embodiments of the present disclosure.

FIG. 3A is a top view of an interposer, in accordance with some embodiments of the present disclosure.

FIG. 3B is a top view of an interposer, in accordance with some embodiments of the present disclosure.

FIG. 3C is a top view of an interposer, in accordance with some embodiments of the present disclosure.

FIG. 3D is a top view of an interposer, in accordance with some embodiments of the present disclosure.

FIG. 3E is a top view of an interposer, in accordance with some embodiments of the present disclosure.

FIG. 3F is a top view of an interposer, in accordance with some embodiments of the present disclosure.

FIG. 4A, FIG. 4B, FIG. 4C, FIG. 4D, FIG. 4E, FIG. 4F, FIG. 4G, and FIG. 4H illustrate one or more operations of a method for manufacturing an interposer, in accordance with some embodiments of the present disclosure.

FIG. 4C-1 is an enlarged view of region “4C” in FIG. 4C, in accordance with some embodiments of the present disclosure.

FIG. 5A, FIG. 5B, FIG. 5C, FIG. 5D, FIG. 5E, FIG. 5F, FIG. 5G, FIG. 5H, and FIG. 5I illustrate one or more operations of a method for manufacturing a package structure, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

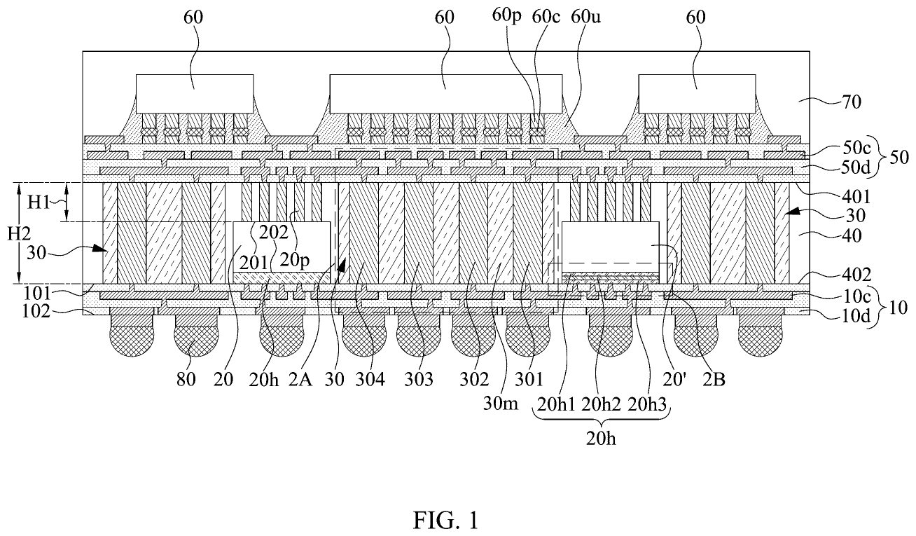

FIG. 1 is a cross-section of a package structure 1, in accordance with some embodiments of the present disclosure. The package structure 1 may include a substrate 10, one or more electronic components 20 and 20′, one or more interposers 30, an encapsulant 40, a redistribution layer (RDL) 50, one or more electronic components 60, an encapsulant 70, and one or more electrical contacts 80.

The package structure 1 may be or include a package-on-package (PoP), fan-out package-on-package (FOPoP), fan-out chip on substrate (FOCoS), fan-out-chip-on-substrate-bridge (FOCoS-B), or the like.

Embodiments of the present disclosure constitute a package structure including a molded interposer with several conductive pins for vertical connection. The conductive pins encapsulated in the molded interposer can be formed by placing in a template with multiple holes during the manufacturing process. The template is used to guide the pins into their predetermined positions, thereby improving the accuracy of the locations. Additionally, the diameter and shape of the template holes can be adjusted based on the pin size. Moreover, the pins of the interposer can exhibit even width, and therefore the molded interposer can meet the requirements of taller heights and small pitch simultaneously. As the molded interposer does not require plating, process time can be shortened as well.

The substrate 10 may include a circuit structure, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some embodiments, the substrate 10 includes a ceramic material, a metal plate, an organic substrate, or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may be or include a redistribution layer (RDL) including one or more dielectric layers 10d and conductive layers 10c at least partially covered by or embedded in the dielectric layers 10d. The conductive layers 10c may include conductive traces, pads, and conductive vias. The substrate 10 may include a top surface 101 and a bottom surface opposite to the top surface 101. In some embodiments, the substrate 10 includes one or more conductive pads (not shown) exposed by the top surface 101 or the bottom surface.

The electronic components 20 and 20′ may be disposed on the top surface 101 of the substrate 10. The electronic components 20 and 20′ may be attached to the substrate 10 via an adhesive layer 20h. In some embodiments, the adhesive layer 20h may be a single layer. The adhesive layer 20h may be or include a conductive material, for example, aluminum (Al), copper (Cu), chromium (Cr), tin (Sn), gold (Au), silver (Ag), nickel (Ni), stainless steel, a mixture, an alloy, or other combination thereof. In another embodiment, the adhesive layer 20h may include multiple layers 20h1, 20h2, and 20h3. For example, the adhesive layers 20h1, 20h2, and 20h3 may be or include dielectric layers. In some embodiments, the electronic components 20 and 20′ may have an active surface 201 and a backside surface 202 opposite to the active surface 201. The active surface 201 of the electronic components 20 and 20′ faces away from the substrate 10. The backside surface 202 may be attached to the top surface 101 of the substrate 10 via the adhesive layer 20h. The electronic components 20 and 20′ may be electrically connected to the RDL 50.

The size of the electronic components 20 and 20′ may be substantially identical. For example, the width and/or the thickness of the electronic components 20 and 20′ may be the same. In another embodiment, the electronic components 20 and 20′ may have different sizes (such as thickness or width). For example, thicknesses of the electronic components 20 and 20′ may vary.

Each of the electronic components 20 and 20′ may be a chip or die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the electronic components 20 and 20′ include an active device, e.g., an ASIC, a PMIC, or the like. For example, the electronic components 20 and 20′ may be or include a storage component or memory, e.g., a dynamic random access memory (DRAM). In some embodiments, the electronic components 20 and 20′ may be an interconnection structure, such as a bridge die.

The RDL 50 may be disposed over the substrate 10 and the electronic components 20 and 20′. In some embodiments, the RDL 50 may include circuit layers. The RDL 50 includes one or more dielectric layers 50d and conductive layers 50c at least partially covered by or embedded in the dielectric layers 50d. The conductive layers 50c may include conductive traces, pads, and conductive vias. The conductive layers 50c may be or include a conductive material, for example, aluminum (Al), copper (Cu), chromium (Cr), tin (Sn), gold (Au), silver (Ag), nickel (Ni), stainless steel, a mixture, an alloy, or other combination thereof. In some embodiments, a width of the RDL 50 may be substantially identical to a width of the substrate 10. The width of the dielectric layer 50d of the RDL 50 may be substantially identical to a width of the substrate 10.

In some embodiments, the electronic components 20 and 20′ may be electrically connected to the conductive layer 50c of the RDL 50 through one or more conductive pillars 20p. The conductive pillars 20p may be or include a pillar, stud, terminal, pin, or other suitable conductive interconnectors. In some embodiments, the conductive pillars 20p may be formed by vertical wire bonding. The conductive pillars 20p may be or include a conductive material, for example, copper (Cu), aluminum (Al), chromium (Cr), tin (Sn), gold (Au), silver (Ag), nickel (Ni), platinum (Pt), a mixture, an alloy, or other combination thereof.

The interposers 30 may be disposed on the top surface 101 of the substrate 10 and laterally overlapping the electronic components 20 and 20′. The interposer 30 may be disposed between and electrically connected to the RDL 50 and the top surface 101 of the substrate 10. The interposer 30 may be electrically connected to the conductive layers 50c of the RDL 50. In some embodiments, the interposer 30 contacts the RDL 50 and the substrate 10.

In some embodiments, the interposer 30 may be a conductive pillar module or a molded interposer. The interposer 30 may include one or more pins 301, 302, 303, and 304 and an encapsulant 30m encapsulating the pins 301, 302, 303, and 304. The encapsulant 30m may expose the top surface and the bottom surface of the pins 301, 302, 303, and 304. In some embodiments, a lateral surface of the encapsulant 30m may be substantially parallel to and free from contacting a lateral surface of the electronic components 20 and 20′.

In some embodiments, the encapsulant 30m may include an epoxy resin having fillers dispersed therein, a molding compound (e.g., an epoxy molding compound or other molding compound), PI, a phenolic compound or material, a polymer material with silicone dispersed therein, or a combination thereof.

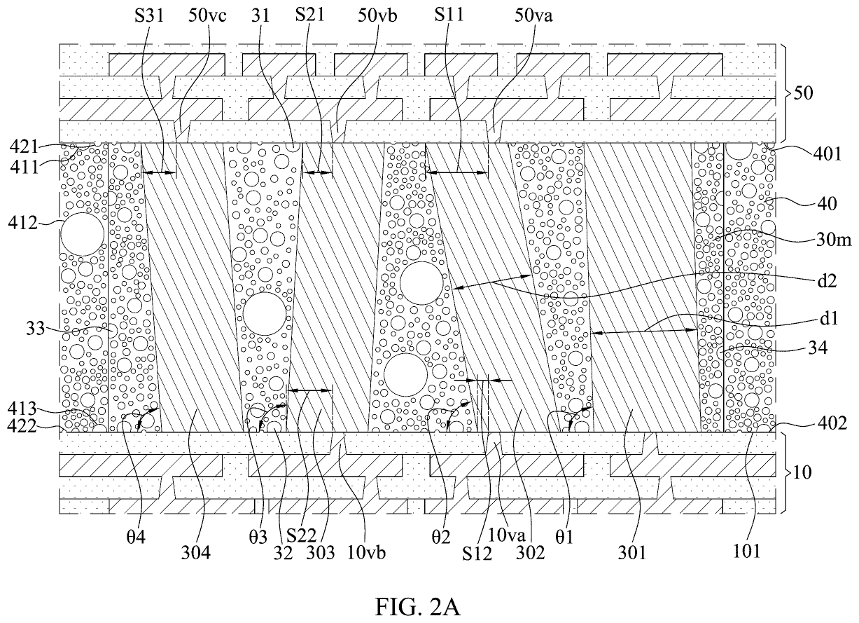

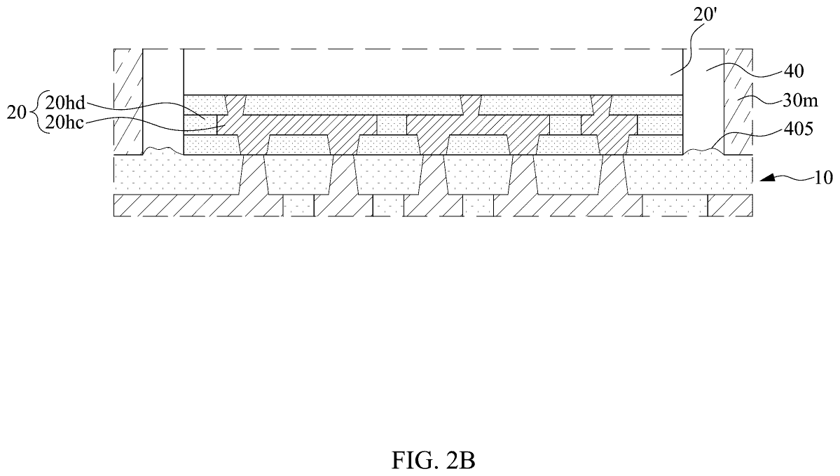

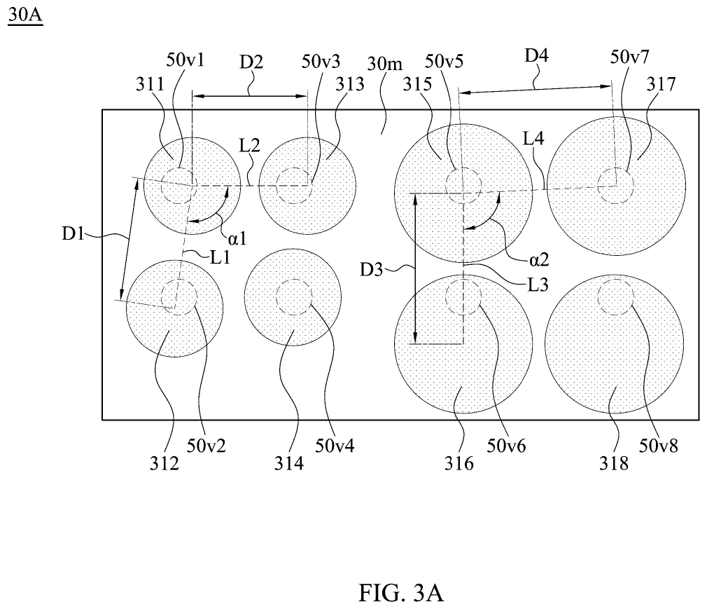

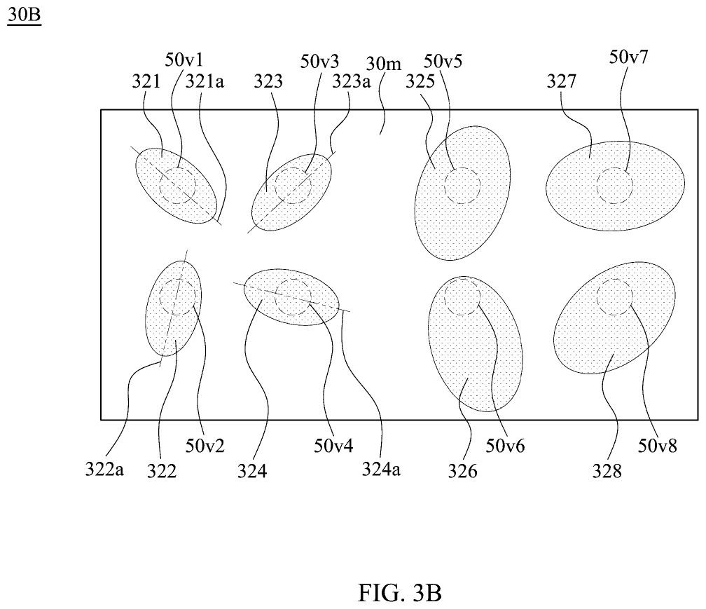

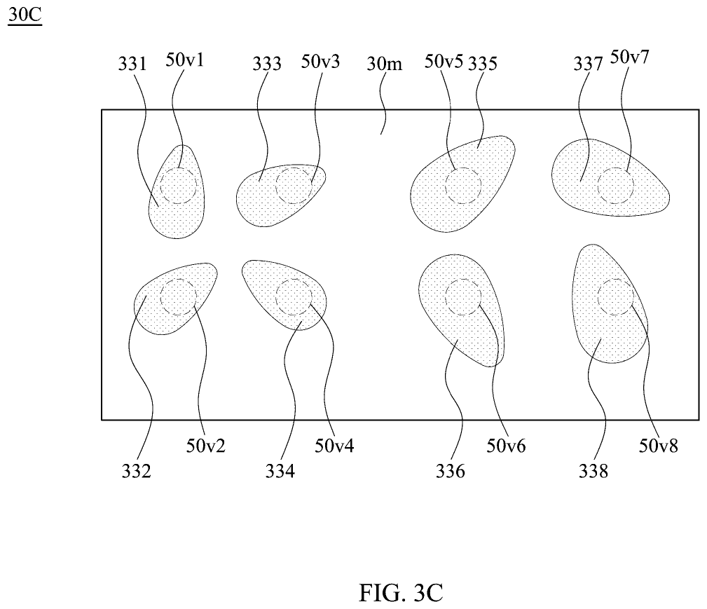

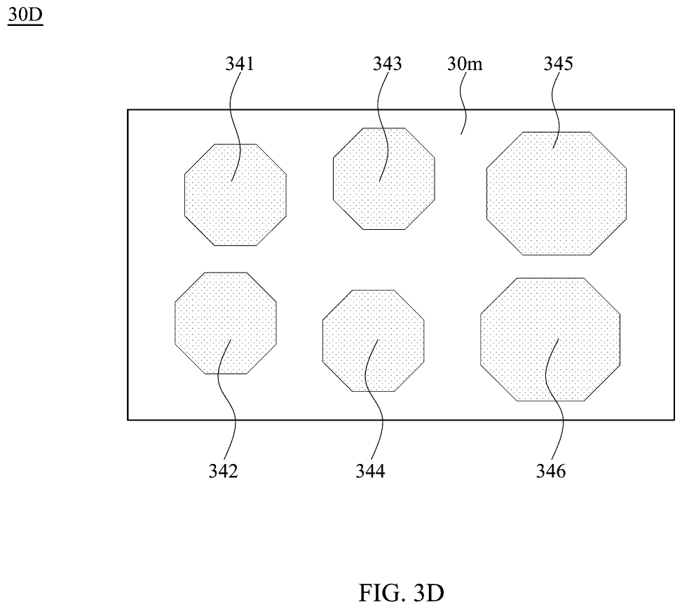

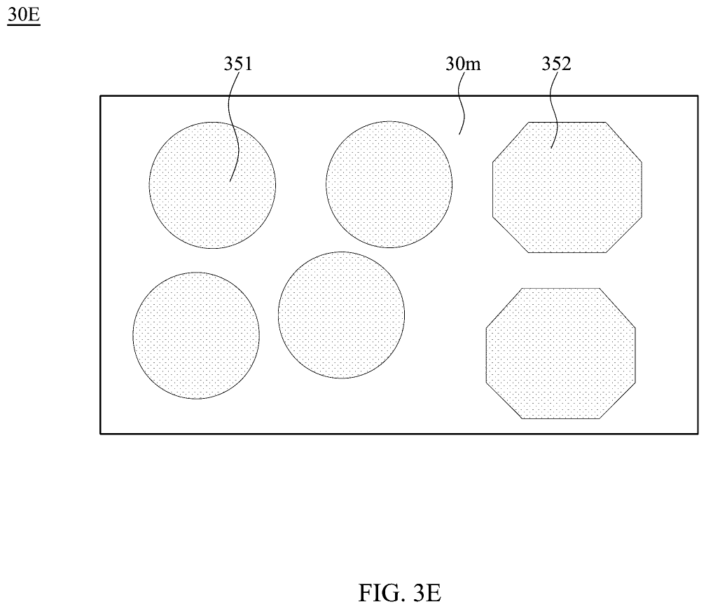

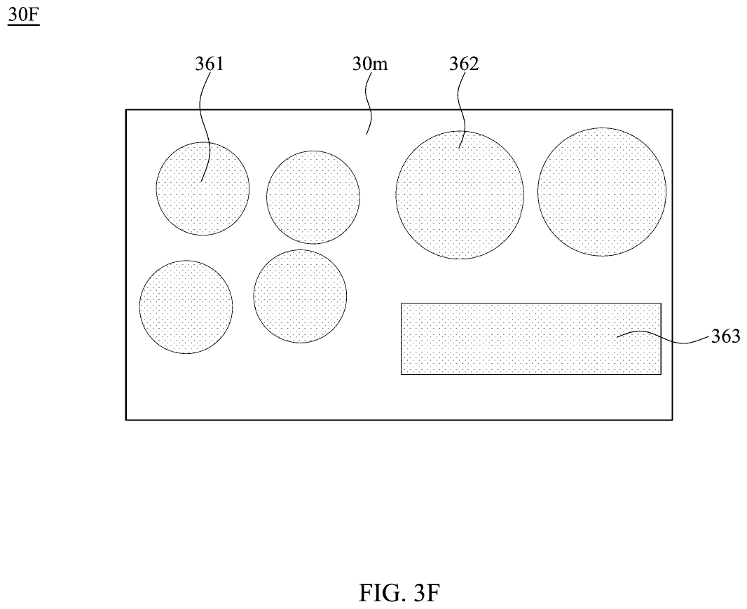

In some embodiments, the pins 301, 302, 303, and 304 may have the same diameter. In other embodiments, the pins 301, 302, 303, and 304 may have different diameters. For example, the diameter of the pin 301 is greater than that of the pin 302 (see FIG. 2A). In some embodiments, the diameter of the pins 301, 302, 303, and 304 may be about 15, 20, 30, 40, 50, 60, 70, 80 μm, or more. The shape of the pins 301, 302, 303, and 304 may be substantially identical (see details in FIGS. 3A to 3F).

The pins 301, 302, 303, and 304 may be disposed and extend between the RDL 50 and the top surface 101 of the substrate 10. In some embodiments, the pin 301 is spaced apart from the pin 302. The pin 303 may be spaced apart from the pin 302. The pin 302 may be disposed between the pins 301 and 303. The pin 304 may be spaced apart from the pin 303. The pin 303 may be disposed between the pins 302 and 304. In some embodiments, the pitch (the distance between adjacent pins) of the pins 301, 302, 303, and 304 may be less than or equal to 25 μm.

The pins 301, 302, 303, and 304 may have a substantially same height (vertical length) H2. In some embodiments, a height H1 of the conductive pillars 20p is different from the height H2 of the pin 301. For example, the height H1 can be less than the height H2. In some embodiments, the height H2 of the pins 301, 302, 303, and 304 may be in a range of 0.1 to 1 mm, preferably less than or equal to 0.2 mm. In some embodiments, a diameter of the conductive pillars 20p is different from that of the pin 301. For example, the diameter of the conductive pillars 20p is less than that of the pin 301.

In some embodiment, the conductive pillars 20p may be parallel to each other. The conductive pillars 20p may tilted or inclined with respect to the top surface 401 of the encapsulant 40. The tilted direction of a first one of the conductive pillars 20p is substantially identical to the tilted direction of a second one of the conductive pillars 20p with respect to the top surface 401 of the encapsulant 40. In other embodiments, the conductive pillars 20p may be substantially parallel to the pins 301, 302, 303, and 304 of the interposer 30.

The pins 301, 302, 303, and 304 may be conductive, such as electrical, thermal, or ground pins. In one embodiment, the pins 301, 302, 303, and 304 are all electrical conductive pins. In another embodiment, the pins 301 and 304 may be ground pins, and the pins 302 and 303 electrical conductive pins.

In some embodiments, the pins 301 and 304 may be thermal conductive pins, free of electrical current therethrough, and the pins 302 and 303 may be electrical conductive pins. The thermal conductive pins 301 and 304 surround the electrical conductive pins 302 and 303. In such a case, the thermal conductive pin 301 may be connected to the dielectric layer 50d of the RDL 50. The electrical conductive pin 302 is electrically connected to the conductive layer 50c of the RDL 50.

The pins 301, 302, 303, and 304 may be or include a pillar, stud, terminal, or other suitable conductive interconnectors. The pins 301, 302, 303, and 304 may be or include a conductive material, for example, copper (Cu), aluminum (Al), chromium (Cr), tin (Sn), gold (Au), silver (Ag), nickel (Ni), platinum (Pt), a mixture, an alloy, or other combination thereof.

The pins 301, 302, 303, and 304 may be pre-formed and then encapsulated by the encapsulant 30m to form the interposer 30. The top surface of the encapsulant 30m is substantially aligned with the top surfaces of the pins 301, 302, 303, and 304, and the bottom surface of the encapsulant 30m is substantially aligned with the bottom surfaces of the pins 301, 302, 303, and 304. In some embodiments, a lateral surface of the encapsulant 30m is substantially parallel to and free from contacting a lateral surface of the electronic component 20 and 20′.

The encapsulant 40 may encapsulate the electronic components 20 and 20′, the conductive pillars 20p, and the interposers 30. The encapsulant 40 may expose an end of the conductive pillars 20p and top surfaces of the pins within the interposer 30. The interposer 30 may be spaced apart from the conductive pillars 20p by the encapsulant 40. In some embodiments, the conductive pillars 20p are formed by wire bonding, and the package structure 1 may be free of a seed layer between the conductive pillars 20p and the active surface 201 of the electronic component 20 or 20′. The encapsulant 40 may have a top surface 401 and a bottom surface 402 opposite to the top surface 401. The top surface 401 is substantially coplanar with or aligned with the end of the conductive pillars 20p and the top surfaces of the pins (such as pins 301, 302, 303, and 304) of the interposers 30. That is, the top surfaces of the pins 301, 302, 303, and 304 of the interposers 30 are exposed by the top surface 401 of the encapsulant 40. The bottom surface 402 is in contact with the top surface 101 of the substrate. The bottom surface 402 may be substantially coplanar with or aligned with the bottom surfaces of the pins (such as pins 301, 302, 303, and 304) of the interposers 30. In some embodiments, a width of the encapsulant 40 is substantially identical to that of the substrate 10.

In some embodiments, the encapsulant 40 may include an epoxy resin having fillers dispersed therein, a molding compound (e.g., an epoxy molding compound or other molding compound), PI, a phenolic compound or material, a polymer material with silicone dispersed therein, or a combination thereof. In some embodiments, the encapsulant 40 may include a material different from the encapsulant 30m. In other embodiments, the encapsulant 40 may include a material the same as the encapsulant 30m.

In some embodiments, the electronic components 60 may be disposed on the RDL 50 and partially vertically overlap the interposer 30. The electronic components 60 may include one or more conductive terminals 60p protruding from the underside of the electronic components 60. The electronic components 60 may be electrically connected to the RDL 50 via connectors 60c. The connectors 60c may include conductive bumps, solder elements, solder balls, micro bumps, or the like. The connectors 60c may be or include a conductive material, for example, aluminum (Al), copper (Cu), chromium (Cr), tin (Sn), gold (Au), silver (Ag), nickel (Ni), stainless steel, a mixture, an alloy, or other combination thereof.

In some embodiments, a protective element 60u may cover or encapsulate the connectors 60c, the electronic components 60, and the RDL 50. The protective element 60u may partially cover the RDL 50. In some embodiments, the protective element 60u may encapsulate the bottom surfaces of the electronic components 60 and partially cover the lateral surfaces of the electronic components 60. In some embodiments, the protective element 60u may be or include an underfill or a dielectric layer. The underfill may include an epoxy resin having fillers dispersed therein, a molding compound (e.g., an epoxy molding compound or other molding compound), polyimide (PI), a phenolic compound or material, a polymer material with silicone dispersed therein, or a combination thereof.

Each of the electronic components 60 may be a chip or die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the electronic components 60 include an active device, e.g., an ASIC, a PMIC, or the like. For example, the electronic components 60 may be or include a storage component or memory, e.g., a dynamic random access memory (DRAM). In some embodiments, the electronic components 60 may be different from the electronic components 20 and 20′. For example, the electronic components 60 may be ASICs and/or memory, and the electronic components may be bridge dies and/or PMICs.

The encapsulant 70 may encapsulate or cover the electronic components 60, the protective elements 60u, and the RDL 50. The encapsulant 70 may cover the top surfaces of the electronic components 60. The electronic components 60 may be spaced apart by the encapsulant 70. In some embodiments, a width of the encapsulant 70 is substantially identical to that of the RDL 50.

In some embodiments, the encapsulant 70 may include an epoxy resin having fillers dispersed therein, a molding compound (e.g., an epoxy molding compound or other molding compound), PI, a phenolic compound or material, a polymer material with silicone dispersed therein, or a combination thereof.

In some embodiments, the electrical contacts 80 may be disposed on the bottom surface 102 of the substrate 10. The electrical contacts 80 may be disposed on a side of the substrate 10 opposite to the encapsulant 40. The electrical contacts 80 may be electrically connected to the pins of the interposers 30. The electrical contacts 80 may include conductive bumps, solder elements, solder balls, or the like. The electrical contacts 80 may be or include a conductive material, for example, aluminum (Al), copper (Cu), chromium (Cr), tin (Sn), gold (Au), silver (Ag), nickel (Ni), stainless steel, a mixture, an alloy, or other combination thereof.

The proposed package structure 1 includes the molded interposer 30 equipped with several conductive pins for vertical connections. The diameter and shape of the conductive pins can vary. The conductive pins of the molded interposer 30 can have taller heights and smaller pitches at the same time. Additionally, since the molded interposer eliminates the need for a plating process, the overall manufacturing time can be reduced.

FIG. 2A is an enlarged view of region “2A” in FIG. 1, in accordance with some embodiments of the present disclosure. Referring to FIG. 2A, the pins 301, 302, 303, and 304 of the interposer 30 may be tilted and angled with respect to the top surface 101 in different directions. The pin 301 is tilted and angled with respect to the top surface 101 in a direction different from the pin 302. The pin 302 is tilted and angled with respect to the top surface 101 in a direction different from the pin 303. In some embodiments, the pins 301, 302, 303, and 304 may be at different angles. The pins 301, 302, 303, and 304 may be tilted to shift about 1, 1.5, or 2 μm. That is, the pins 301, 302, 303, and 304 may be substantially perpendicular to the top surface 101 of the substrate 10 with a slightly tilt.

In some embodiments, the pin 301 may form an angle θ1 with the top surface 101 of the substrate 10. The pin 302 may form an angle θ2 with the top surface 101 of the substrate 10. The pin 303 may form an angle θ3 with the top surface 101 of the substrate 10. The pin 304 may form an angle θ4 with the top surface 101 of the substrate 10. The angle θ1 of the pin 301 may be different from the angle θ2 of the pin 302, the angle θ3 of the pin 303, and the angle θ4 of the pin 304. The angle θ1 of the pin 301 is greater than the angle θ2 of the pin 302. In one embodiment, the angle θ1 of the pin 301 may be closer to 90° than the angles θ2, θ3, and θ4. As the angle (tilted degree) of the pin 301 is less than that of the pin 302, a length of the pin 301 may be less than a length of the pin 302. In some embodiments, the pins 302 and 303 may be tilted in different directions at different tilted angles. For example, the angle θ2 of the pin 302 may be less than the angle θ3 of the pin 303. That is, the tilted degree of the pin 302 is greater than the tilted degree of the pin 303 with regard to the bottom surface of the encapsulant 30m. In some embodiments, the pins 302 and 304 may be tilted in the same direction at different angles.

In some embodiments, the pins 301, 302, 303, and 304 of the interposer 30 may have different diameters. The diameter d1 of the pin 301 is different from the diameter d2 of the conductive pin 302. The diameter d1 of the pin 301 is greater than the diameter d2 of the pin 302. In some embodiments, the pins 302, 303, and 304 may have the same diameter but different from the pin 301.

The top surface and the bottom surface of the interposer 30 may both be grinded. Therefore, the roughness of the top surface of the pin 301 is substantially identical to the roughness of the bottom surface of the pin 301. The roughness of the top surface of the pin 302 is substantially identical to the roughness of the bottom surface of the pin 302. The roughness of the top surface of the pin 303 is substantially identical to the roughness of the bottom surface of the pin 303. The roughness of the top surface of the pin 304 is substantially identical to the roughness of the bottom surface of the pin 304.

In some embodiments, the conductive layer 50c of the RDL 50 may include one or more conductive vias 50va, 50vb, and 50vc covered by the dielectric layer 50d. The conductive layer 10c of the substrate 10 may include one or more conductive vias 10va and 10vb covered by the dielectric layer 10d. The conductive vias 50va, 50vb, and 50vc are disposed on and taper toward the top surface of the interposer 30, and connected to the pins of the interposer 30. The conductive vias 10va and 10vb are disposed on and taper toward the bottom surface of the interposer 30, and connected to the pins of the interposer 30. In some embodiments, the conductive vias 50va, 50vb, 50vc, 10va, and 10vb are misaligned with pins of the interposer 30.

The conductive via 50va may be disposed on the pin 302 and contacts the top surface of the pin 302. The conductive via 50va may expose a portion of the top surface of the pin 302. That is, the conductive via 50va does not entirely cover the top surface of the pin 302. In some embodiments, the center of the conductive via 50va may misalign the center of the top surface of the pin 302. Accordingly, a distance S11 between a left edge of the pin 302 and a left edge of the conductive via 50va is greater than a distance between a right edge of the pin 302 and a right edge of the conductive via 50va.

The conductive via 10va may be disposed under the pin 302 and contacts the bottom surface of the pin 302. The conductive via 10va may expose a portion of the bottom surface of the pin 302. That is, the conductive via 10va does not entirely cover the bottom surface of the pin 302. In some embodiments, the center of the conductive via 10va may misalign the center of the bottom surface of the pin 302. Accordingly, a distance S12 between a left edge of the pin 302 and a left edge of the conductive via 10va is less than a distance between a right edge of the pin 302 and a right edge of the conductive via 10va.

The conductive via 50vb may be disposed on the pin 303 and contacts the top surface of the pin 303. The conductive via 50vb may expose a portion of the top surface of the pin 303. That is, the conductive via 50vb does not entirely cover the top surface of the pin 303. In some embodiments, the center of the conductive via 50vb may misalign the center of the bottom surface of the pin 303. Accordingly, a distance S21 between a left edge of the pin 303 and a left edge of the conductive via 50vb is less than a distance between a right edge of the pin 303 and a right edge of the conductive via 50vb. In some embodiments, the distance S11 between the left edge of the pin 302 and the left edge of the conductive via 50va is different from (such as, greater than) the distance S12 between the left edge of the pin 303 and a left edge of the conductive via 50vb.

The conductive via 10vb may be disposed under the pin 303 and contacts the bottom surface of the pin 303. The conductive via 10vb may expose a portion of the bottom surface of the pin 303. That is, the conductive via 10vb does not entirely cover the bottom surface of the pin 303. In some embodiments, the center of the conductive via 10vb may misalign the center of the bottom surface of the pin 303. Accordingly, a distance S22 between a left edge of the pin 303 and a left edge of the conductive via 10vb is greater than a distance between a right edge of the pin 303 and a right edge of the conductive via 10vb. In some embodiments, the distance S12 between the left edge of the pin 302 and the left edge of the conductive via 50va is different from (such as, less than) the distance S22 between the left edge of the pin 304 and the left edge of the conductive via 50vc.

The conductive via 50vc may be disposed on the pin 304 and contacts the top surface of the pin 304. The conductive via 50vc may expose a portion of the top surface of the pin 304. That is, the conductive via 50vc does not entirely cover the top surface of the pin 304. In some embodiments, the center of the conductive via 50vc may misalign the center of the bottom surface of the pin 304. Accordingly, a distance S31 between a left edge of the pin 304 and a left edge of the conductive via 50vc is less than a distance between a right edge of the pin 304 and a right edge of the conductive via 50vc. In some embodiments, the distance S11 between the left edge of the pin 302 and the left edge of the conductive via 50va is different from (such as, greater than) the distance S31 between the left edge of the pin 304 and a left edge of the conductive via 50vc.

Referring to FIG. 2A, the encapsulant 40 may include a plurality of fillers. Each of the fillers of the encapsulant 40 may have different filler sizes. In some embodiments, the fillers may contact the RDL 50 and the substrate 10. The encapsulant 40 may include fillers 411, 412, and 413. In some embodiments, the filler 411 is incomplete since a portion is removed by grinding process. The removed portion of the filler 411 may be about 50% of the original amount. In some embodiments, the removed portion of the filler 411 may be less than 50% of the original amount. The top surface of the filler 411 is formed by the grinding process to be substantially planar. Similar to the filler 411, the filler 413 is also incomplete. The removed portion of the filler 413 may be about 50% of the original amount. In some embodiments, the removed portion of the filler 413 may be less than 50% of the original amount. The top surface of the filler 413 is formed by the grinding process to be substantially planar. In some embodiments, the filler 412 may have a relatively larger diameter. For example, the diameter of the filler 412 may be equal to or greater than the thickness of one dielectric layer 50d of the RDL 50.

In some embodiments, the encapsulant 40 may have one or more recesses 421 recessed from the top surface 401, as some of the fillers may be entirely removed during the grinding process. A portion of the dielectric layer 50d may fill in the recesses 421. Accordingly, the portion of the dielectric layer 50d may laterally (or horizontally) overlap the interposer 30 (i.e., the pins 301, 302, 303, and 304). In some embodiments, the encapsulant 40 may have one or more recesses 422 recessed from the bottom surface, as some of the fillers may be entirely removed during the grinding process. A portion of the dielectric layer of the substrate 10 may fill in the recesses 422. Accordingly, the portion of the dielectric layer of the substrate 10 may laterally (or horizontally) overlap the interposer 30 (i.e., the pins 301, 302, 303, and 304). In some embodiments, both of the top surface and the bottom surface of the encapsulant 40 may be grinded. In other embodiments, the grinding process may merely performed on one of the top surface and the bottom surface of the encapsulant 40.

In some embodiments, the encapsulant 30m may include a plurality of fillers. Each of the fillers of the encapsulant 30m may have different filler sizes. The encapsulant 30m may be similar to the encapsulant 40. For example, both of the top surface and the bottom surface of the encapsulant 30m may be grinded. In some embodiments, the fillers may contact the RDL 50 and the substrate 10.

The encapsulant 30m may include fillers 31, 32, 33, and 34. In some embodiments, the filler 31 is incomplete since a portion is removed by grinding process. The removed portion of the filler 31 may be about 50% of the original amount. In other embodiments, the removed portion of the filler 31 may be less than 50% of the original amount. The top surface of the filler 31 is formed by the grinding process to be substantially planar. That is, the top surface of the filler 31 may be substantially coplanar to or aligned with the top surface of the encapsulant 30m (and the top surface 401 of the encapsulant 40). Similar to the filler 31, the filler 32 is also incomplete. The removed portion of the filler 32 may be less than 50% of the original amount. In some embodiments, the removed portion of the filler 32 may be about or more than 50% of the original amount. The bottom surface of the filler 32 is formed by the grinding process to be substantially planar. That is, the bottom surface of the filler 32 may be substantially coplanar to or aligned with the bottom surface of the encapsulant 30m (and the bottom surface 402 of the encapsulant 40).

In some embodiments, the filler 33 is incomplete since a portion is removed by dicing, sawing, or singulation. The removed portion of the filler 33 may be about 50% of the original amount. In other embodiments, the removed portion of the filler 31 may be less than or more than 50% of the original amount. The lateral surface (left lateral surface) of the filler 33 is formed by the sawing process to be substantially planar. That is, the left lateral surface of the filler 33 may be substantially coplanar to or aligned with the left lateral surface of the encapsulant 30m. In some embodiments, the filler 34 is incomplete since a portion is removed by dicing, sawing, or singulation. The removed portion of the filler 34 may be about 50% of the original amount. In other embodiments, the removed portion of the filler 31 may be less than or more than 50% of the original amount. The lateral surface (right lateral surface) of the filler 34 is formed by the sawing process to be substantially planar. That is, the right lateral surface of the filler 33 may be substantially coplanar to or aligned with the right lateral surface of the encapsulant 30m. In some embodiments, an interface between the encapsulants 30m and 40 may be substantially perpendicular to the top surface 101 of the substrate 10. The pins 301, 302, 303, and 304 may be apart from the interface of the encapsulants 30m and 40.

FIG. 2B is an enlarged view of region “2B” in FIG. 1, in accordance with some embodiments of the present disclosure. Referring to FIG. 2B, the adhesive layer 20h may be or include a circuit layer that includes one or more dielectric layers 20hd and conductive layers 20hc at least partially covered by or embedded in the dielectric layers 20hd. The conductive layers 20hc may include conductive traces, pads, and conductive vias. The conductive layers 20hc may be or include a conductive material, for example, aluminum (Al), copper (Cu), chromium (Cr), tin (Sn), gold (Au), silver (Ag), nickel (Ni), stainless steel, a mixture, an alloy, or other combination thereof.

FIG. 2B shows that the bottom surface of the encapsulant 40 may not be grinded, and thus an interface 405 of the encapsulant 40 and the substrate 10 may be irregular. In some embodiments, the interface 405 may be recessed upward, i.e., away from the substrate 10.

FIG. 3A is a top view of an interposer 30A, in accordance with some embodiments of the present disclosure. The interposer 30A may an embodiment of the interposer 30. The interposer 30A includes multiple pins 311, 312, 313, 314, 315, 316, 317, and 318, and the encapsulant 30m encapsulating the same. FIG. 3A also shows the locations of conductive vias 50v1, 50v2, 50v3, 50v4, 50v5, 50v6, 50v7, and 50v8 of the RDL 50.

The pins 311 to 318 may be rounded in the top view. That is, the top surfaces of the pins 311 to 318 are rounded. The pins 311 to 318 may be spaced apart from each other by the encapsulant 30m. In some embodiments, the pins 311 to 318 may be arranged in a row or array. For example, the pins 311, 312, 313, and 314 may be arranged in an array, and the pins 315, 316, 317, and 318 may be arranged in a separate array. The two arrays may be separated by a distance greater than the distance between individual pins. In some embodiments, the two arrays may be configured to perform different functions, such as thermal conductivity, electrical connection, or grounding. The pins 311 to 318 may be arranged in a predetermined pattern.

In some embodiments, the size (diameter) of the pins 311, 312, 313, and 314 may be the same, and the size (diameter) of the pins 315, 316, 317, and 318 may be the same. The size (diameter) of the pins 311, 312, 313, and 314 may be different from (for example, less than) that of the pins 315, 316, 317, and 318. For example, the diameter of the pins 315, 316, 317, and 318 may be 1.2 times, 1.5 times, 1.8 times, or twice the diameter of the pins 311, 312, 313, and 314, or more.

The pin 311 may be spaced apart from the pins 312 and 313. The pin 314 may be spaced apart from the pins 312 and 313. In some embodiments, a distance D1 between a center of the pin 311 and a center of the pin 312 is different from a distance D2 between a center of the pin 311 and a center of the pin 313. For example, the distance D1 can be greater than the distance D2. In some embodiments, an imaginary line L1 connects the centers of pins 311 and 312, while another imaginary line L2 connects the centers of pins 311 and 313. The lines L1 and L2 form an angle α1, which may exceed 90°, such as 105°,110°, or 120° or more.

The pin 315 may be spaced apart from the pins 316 and 317. The pin 318 may be spaced apart from the pins 316 and 317. In some embodiments, a distance D3 between a center of the pin 315 and a center of the pin 316 is different from a distance D4 between a center of the pin 315 and a center of the pin 317. For example, the distance D3 can be less than the distance D4. In some embodiments, an imaginary line L3 connects the centers of pins 315 and 316, while another imaginary line L4 connects the centers of pins 315 and 317. The lines L3 and L4 form an angle α2, which may approximately 90°, such as 85°, 90°, or 95°. That is, the angle α1 can be greater than the angle α2.

Referring to FIG. 3A, the conductive vias 50v1, 50v2, 50v3, 50v4, 50v5, 50v6, 50v7, and 50v8 of the RDL 50 are arranged in an array. The conductive vias 50v1, 50v3, 50v5, and 50v7 may be arranged in a row and spaced apart from each other by the same distance (pitch). The conductive vias 50v2, 50v4, 50v6, and 50v8 may be arranged in a row and spaced apart from each other by the same distance (pitch). In some embodiments, the conductive vias 50v1 and 50v2 may be arranged in a column and spaced apart from each other by a distance same as the distance/pitch in the row. Likewise, the conductive vias 50v3 and 50v4 may be arranged in a column and spaced apart from each other by a distance same as the distance/pitch in the row. The conductive vias 50v5, 50v6 and the conductive vias 50v7, 50v8 may be arranged similarly.

The conductive vias 50v1, 50v2, 50v3, 50v4, 50v5, 50v6, 50v7, and 50v8 may be disposed on the pins 311, 312, 313, 314, 315, 316, 317, and 318, respectively. The conductive vias 50v1, 50v2, 50v3, 50v4, 50v5, 50v6, 50v7, and 50v8 may be misaligned with the pins 311, 312, 313, 314, 315, 316, 317, and 318. For example, the center of the conductive via 50v1 is misaligned with the center of the top surface of the pin 311. In some embodiments, the conductive via 50v6 may be close to a boundary of the top surface of the pin 316.

The area of the top surfaces of the pins 311 to 318 may be greater than the area of the bottom surface of the conductive vias 50v1 to 50v8, such that the conductive vias of the RDL 50 can be entirely located within the pins 311 to 318 for electrical connection. The conductive vias of the substrate 10 may have the same arrangement.

FIG. 3B is a top view of an interposer 30B, in accordance with some embodiments of the present disclosure. The interposer 30B is similar to the interposer 30A in FIG. 3A, differing therefrom in the shape of pins. The interposer 30B includes multiple pins 321, 322, 323, 324, 325, 326, 327, and 328, and the encapsulant 30m encapsulating the same.

Referring to FIG. 3B, the top surfaces of the pins 321, 322, 323, 324, 325, 326, 327, and 328 may be elliptical. The pins 321, 322, 323, 324, 325, 326, 327, and 328 may have different orientations. For example, a major axis 321a of the pin 321 extends along a direction different from a major axis 322a of the pin 322. The major axis 321a of the pin 321 extends along a direction different from a major axis 323a of the pin 323. The major axis 321a of the pin 321 extends along a direction different from a major axis 324a of the pin 324.

The conductive vias 50v1, 50v2, 50v3, 50v4, 50v5, 50v6, 50v7, and 50v8 may be disposed on the pins 321, 322, 323, 324, 325, 326, 327, and 328, respectively. The conductive vias 50v1, 50v2, 50v3, 50v4, 50v5, 50v6, 50v7, and 50v8 may be misaligned with the pins 321, 322, 323, 324, 325, 326, 327, and 328. For example, the center of the conductive via 50v1 is misaligned with the center of the top surface of the pin 321. In some embodiments, the conductive via 50v6 may be close to a boundary of the top surface of the pin 326.

In some embodiments, the pins 321 to 328 may be tilted and thus the top surfaces thereof may be elliptical. In such a case, the top surfaces of the pins 321 to 328 can be enlarged, such that the RDL 50 can be formed on the interposer 30B accurately. The area of the top surfaces of the pins 321 to 328 may be greater than the area of the bottom surface of the conductive vias 50v1 to 50v8, such that the conductive vias of the RDL 50 can be entirely located within the pins 321 to 328 for electrical connection. The conductive vias of the substrate 10 may have the same arrangement.

FIG. 3C is a top view of an interposer 30C, in accordance with some embodiments of the present disclosure. The interposer 30C is similar to the interposer 30A in FIG. 3A, differing therefrom in the shape of pins. The interposer 30C includes multiple pins 331, 332, 333, 334, 335, 336, 337, and 338, and the encapsulant 30m encapsulating the same.

Referring to FIG. 3C, the top surfaces of the pins 331, 332, 333, 334, 335, 336, 337, and 338 may be irregularly rounded, for example in a teardrop shape. The pins 331, 332, 333, 334, 335, 336, 337, and 338 may have different orientations. For example, the tips of the pins 331, 332, 333, 334, 335, 336, 337, and 338 pointing in different directions.

The conductive vias 50v1, 50v2, 50v3, 50v4, 50v5, 50v6, 50v7, and 50v8 may be disposed on the pins 331, 332, 333, 334, 335, 336, 337, and 338, respectively. The conductive vias 50v1, 50v2, 50v3, 50v4, 50v5, 50v6, 50v7, and 50v8 may be misaligned with the pins 331, 332, 333, 334, 335, 336, 337, and 338. For example, the center of the conductive via 50v1 is misaligned with the center of the top surface of the pin 331. In some embodiments, the conductive via 50v3 may be close to a tip of the top surface of the pin 333. In some embodiments, the conductive via 50v6 may be close to a boundary of the top surface of the pin 336.

In some embodiments, the pins 331 to 338 may be tilted and thus the top surfaces thereof may be in a teardrop shape. In such a case, the top surfaces of the pins 331 to 338 can be enlarged, such that the RDL 50 can be formed on the interposer 30C accurately. The area of the top surfaces of the pins 331 to 338 may be greater than the area of the bottom surface of the conductive vias 50v1 to 50v8, such that the conductive vias of the RDL 50 can be entirely located within the pins 331 to 338 for electrical connection. The conductive vias of the substrate 10 may have the same arrangement.

FIG. 3D is a top view of an interposer 30D, in accordance with some embodiments of the present disclosure. The interposer 30D is similar to the interposer 30A in FIG. 3A, differing therefrom in the arrangement of pins. The interposer 30D includes multiple pins 341, 342, 343, 344, 345, and 346, and the encapsulant 30m encapsulating the same. The pins 341, 342, 343, 344, 345, and 346 may be spaced apart from each other by the encapsulant 30m.

Referring to FIG. 3D, the size of the pins 341, 342, 343, and 344 may be substantially different from (less than) that of the pins 345 and 346. The pins 345 and 346 may be arranged in a side of the interposer 30D, and the pins 341 and 342 may be arranged in the opposite side of the interposer 30D. In some embodiments, the top surfaces of the pins 341, 342, 343, 344, 345, and 346 may be in a polygon, for example in an octagon. The pins 341, 342, 343, 344, 345, and 346 may be oriented along the same axis.

During manufacturing, the pins 341, 342, 343, 345, and 346 may be guided and placed into specific holes of a template. Therefore, the shapes of the pins 341, 342, 343, 344, 345, and 346 can provide the mold lock effect, such that the pins 341, 342, 343, 344, 345, and 346 can enhance stability and mitigate the occurrence of tilting. In some embodiments, the interposer 30D with pins in polygon can be arranged at the edges of a panel to provide electrical connection and support simultaneously.

FIG. 3E is a top view of an interposer 30E, in accordance with some embodiments of the present disclosure. The interposer 30E is similar to the interposer 30A in FIG. 3A, differing therefrom in the arrangement of pins. The interposer 30E includes multiple pins 351 and 352, and the encapsulant 30m encapsulating the same. The pins 351 and 352 may be spaced apart from each other by the encapsulant 30m.

Referring to FIG. 3E, the shape of the pins 351 may be different from that of the pins 352. The top surface of pins 351 may be rounded, and that of the pins 352 may be in a polygon, for example in an octagon. The pin 352 may be closer to an edge of the interposer 30E than the pins 351 is. In some embodiments, the pins 351 and 352 may provide different functions. For example, the pins 351 may serve as electrical connection, and the pins 352 in the polygon can serve as the thermal conductivity or grounding.

FIG. 3F is a top view of an interposer 30F, in accordance with some embodiments of the present disclosure. The interposer 30F is similar to the interposer 30A in FIG. 3A, differing therefrom in the arrangement of pins. The interposer 30F includes multiple pins 361, 362, and 363, and the encapsulant 30m encapsulating the same.

Referring to FIG. 3F, the pins 361, 362, and 363 may be spaced apart from each other by the encapsulant 30m. The profile of the top surfaces of the pins 361, 362, and 363 may be different. The shape of the pins 361 and 362 may be the same. The shape of the pins 361 may be different from that of the pins 363. The pins 361 and 362 may be rounded, and the pins 363 may be in a rectangle. The size (diameter) of the pins 361 may be different from that of the pins 362. For example, the diameter of the pins 362 may be greater than that of the pins 361. In some embodiments, the size (area) of the pin 363 may be different from (for example, greater than) that of the pins 361 and 362.

In some embodiments, the pins 361, 362, and 363 may provide different functions. For example, the pins 361 may serve as electrical connection, and the pins 362 and 363 may serve as ground pins.

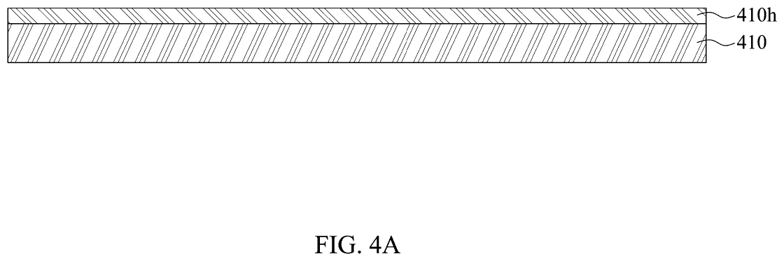

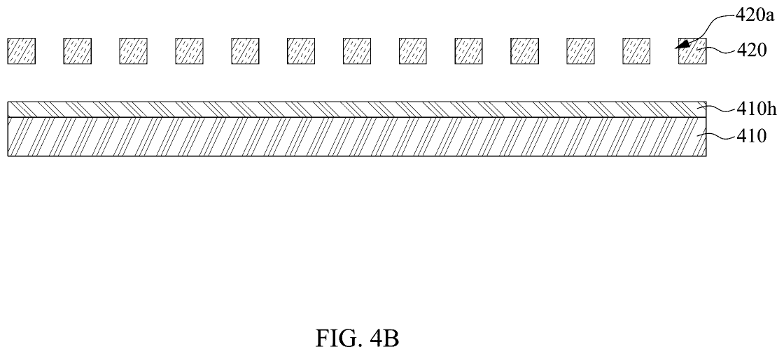

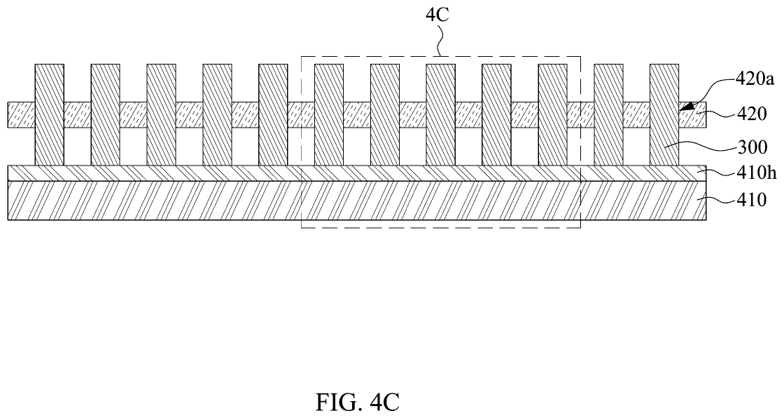

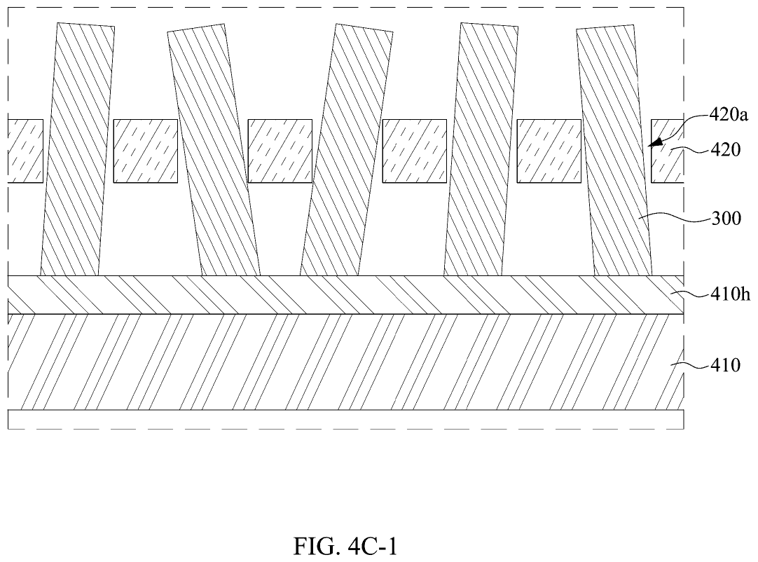

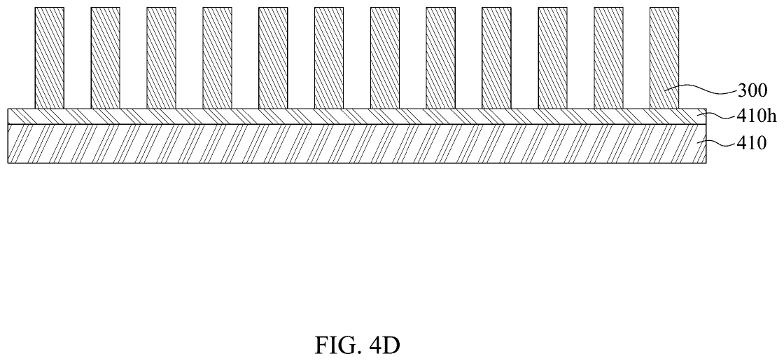

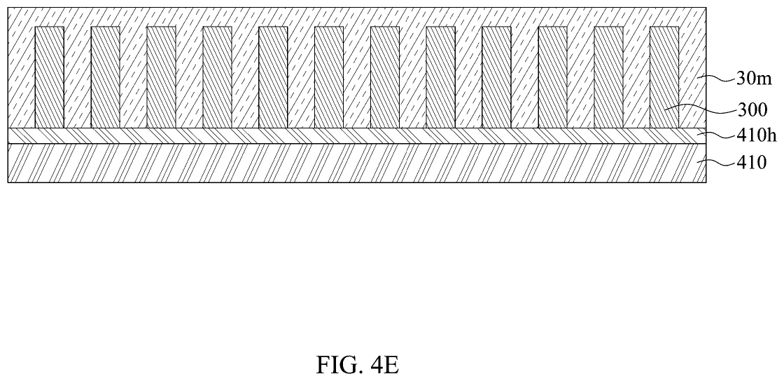

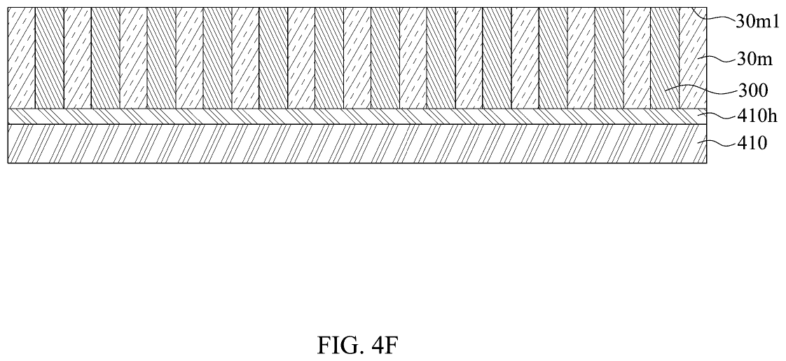

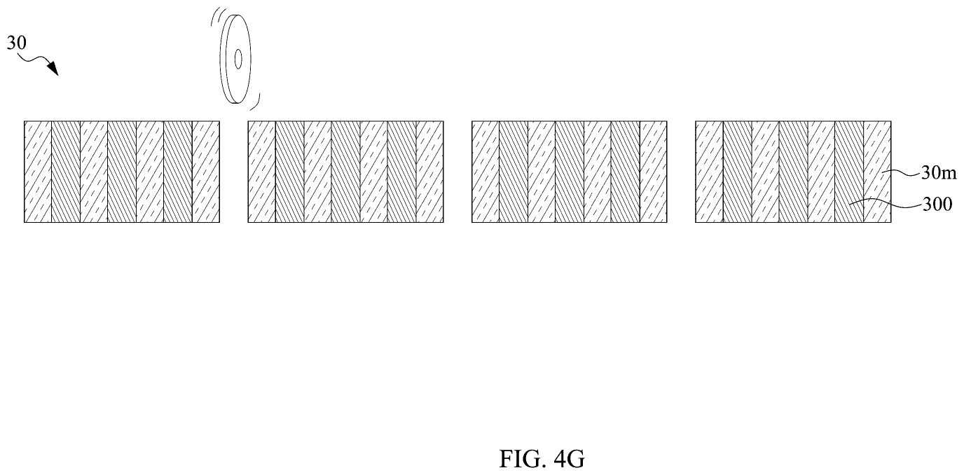

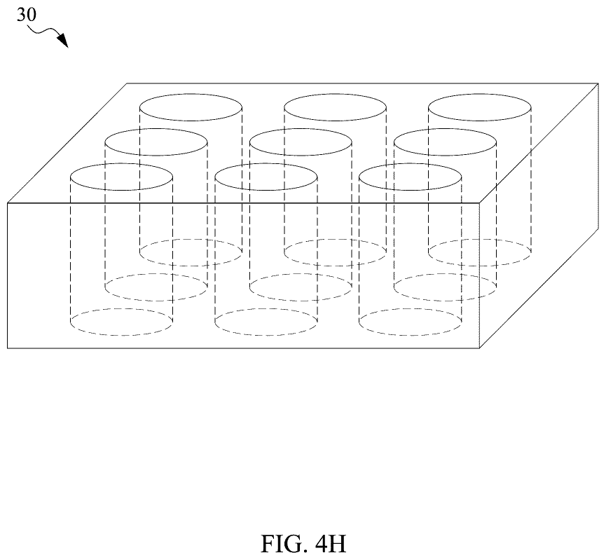

FIG. 4A, FIG. 4B, FIG. 4C, FIG. 4D, FIG. 4E, FIG. 4F, FIG. 4G, and FIG. 4H illustrate one or more operations of a method for manufacturing an interposer 30, in accordance with some embodiments of the present disclosure. FIG. 4C-1 is an enlarged view of region “4C” in FIG. 4C, in accordance with some embodiments of the present disclosure.

Referring to FIG. 4A, a carrier 410 is provided with an adhesive layer 410h disposed on the top surface thereof. In some embodiments, the adhesive layer 410h may be a release film coating.

Referring to FIG. 4B, a template 420 is disposed on the carrier 410. The template 420 may have one or more legs (not shown) contacting the carrier 410 via the adhesive layer 410h for supporting the template 420 thereon. The template 420 may include multiple holes 420a for guiding the pins into predetermined positions, whereby the pins can be arranged in the predetermined pattern. In some embodiments, the diameter and shape of holes 420a can be adjusted based on need.

Referring to FIGS. 4C and 4C-1, pins 300 can be placed in the holes 420a of the template 420. The pins 300 may be disposed on the carrier 410. In some embodiments, a respective one of the pins 300 can be guided and placed into a respective one of the holes 420a. In some embodiments, the diameter of the pins 300 may correspond to that of the holes 420a of the template 420. The pins 300 can penetrate the holes 420a and contact the adhesive layer 410h. Referring to FIG. 4C-1, the diameter of the pins 300 may be less than that of the holes 420a of the template 420. The pins 300 may tilted and angled in different orientations. In some embodiments, the pins 300 may be similar to the pins 301, 302, 303, and 304 of FIG. 1.

Referring to FIG. 4D, the pins 300 can be attached to the carrier 410 through the adhesive layer 410h after which the template 420 can be removed. In some embodiments, a baking process may be performed, such that the pins 300 can be attached to the carrier 410 through the adhesive layer 410h. In some embodiments, the pins 300 can be connected to the carrier 410 through welding or other suitable process.

Referring to FIG. 4E, an encapsulant 30m may be formed on the carrier 410 to encapsulate the pins 300. The encapsulant 30m may be formed by a molding process.

Referring to FIG. 4F, the encapsulant 30m may be grinded to form a planar top surface 30m1 and expose ends (top surfaces) of the pins 300.

Referring to FIG. 4G, the carrier 410 can be removed and the resulting structure singulated. In some embodiments, a dicing operation may be performed. For example, the dicing operation may be a sawing process, such as laser sawing. Then, a plurality of interposers 30 can be formed, as illustrated in the three-dimensional (3D) schematic diagram in FIG. 4H.

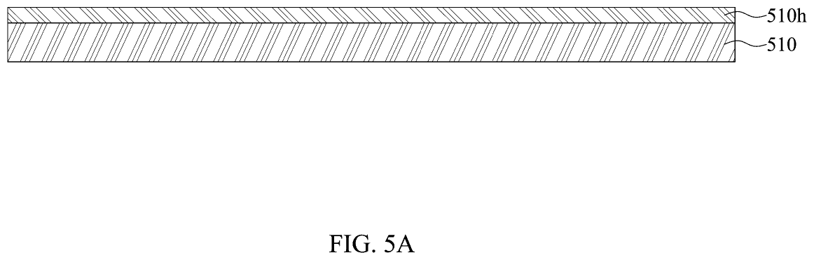

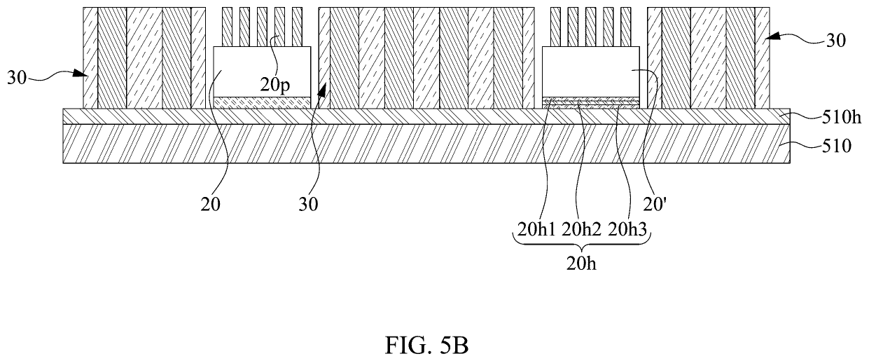

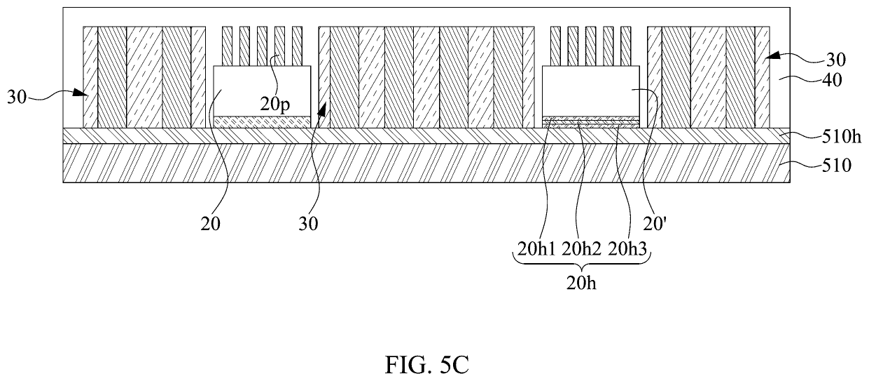

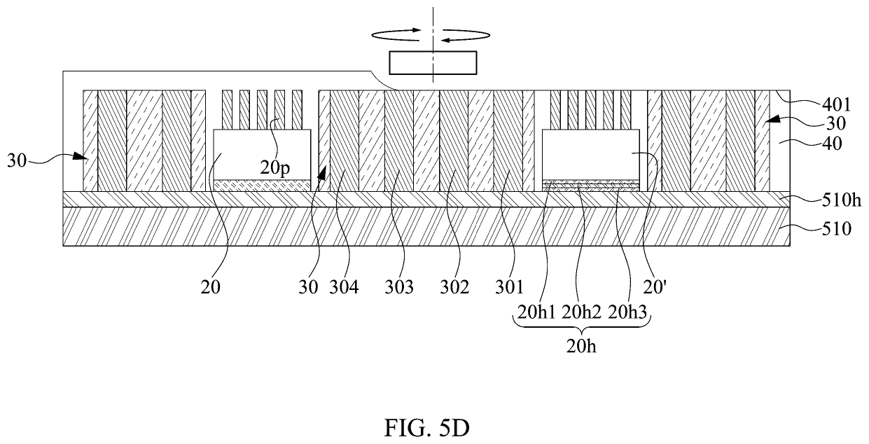

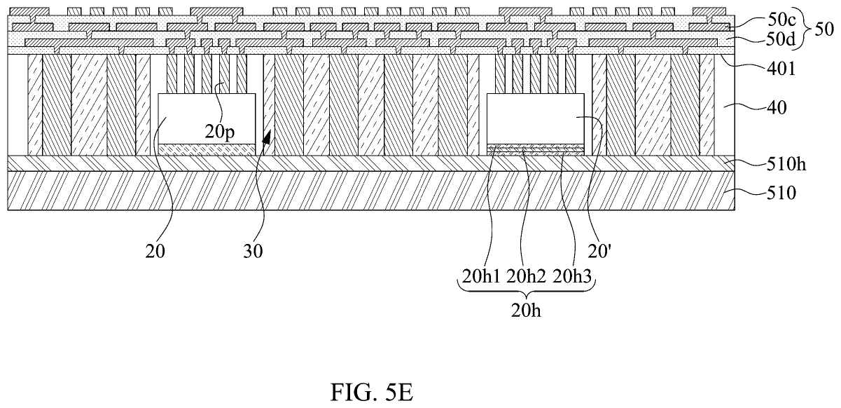

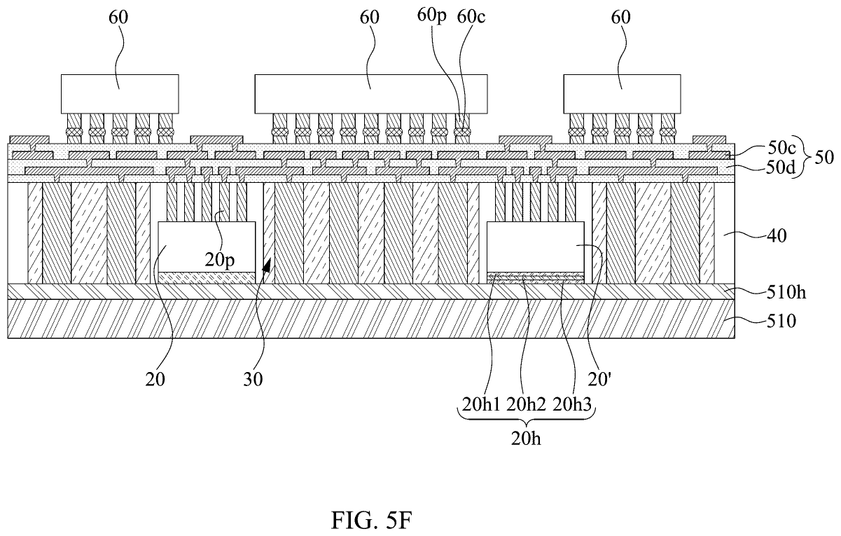

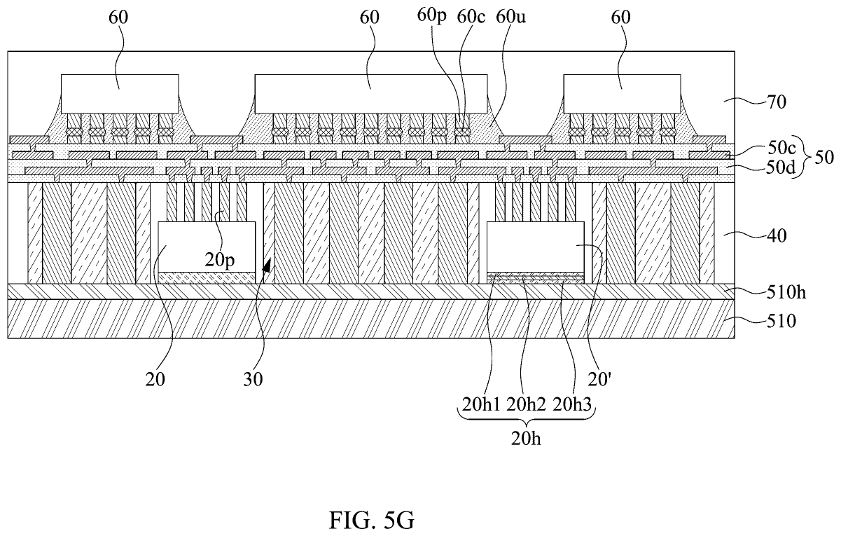

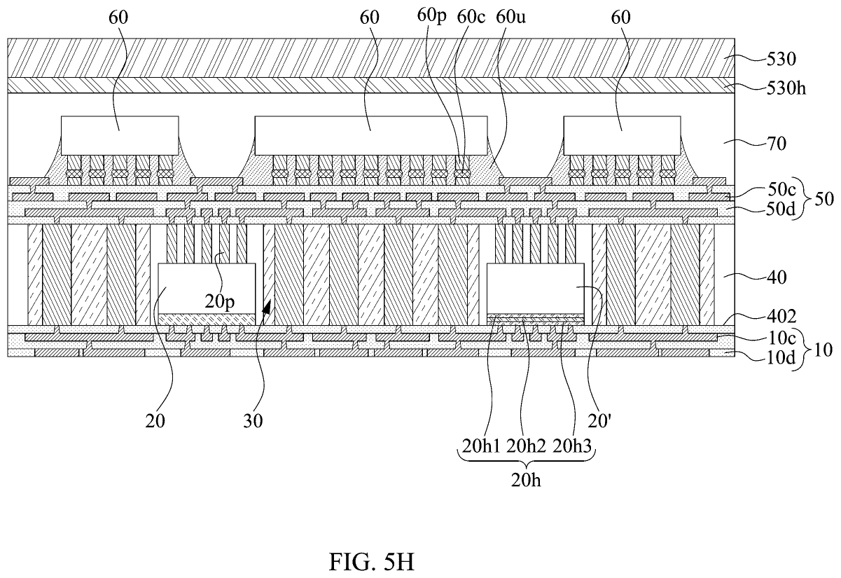

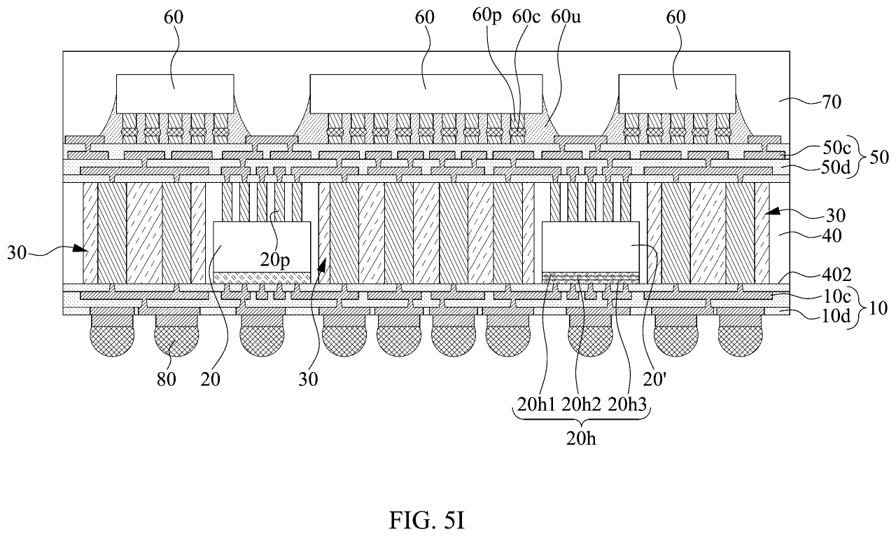

FIG. 5A, FIG. 5B, FIG. 5C, FIG. 5D, FIG. 5E, FIG. 5F, FIG. 5G, FIG. 5H, and FIG. 5I illustrate one or more operations of a method for manufacturing a package structure 1, in accordance with some embodiments of the present disclosure.

Referring to FIG. 5A, a carrier 510 is provided with an adhesive layer 510h disposed on the top surface of the carrier 510. In some embodiments, the adhesive layer 510h may be a release film coating.

Referring to FIG. 5B, one or more electronic components 20 and 20′ and interposers 30 are placed on the carrier 510. The electronic components 20 and 20′ and interposers 30 are attached to the carrier 510. In some embodiments, one or more conductive pillars 20p may be formed on and connected to the electronic component 20 and 20′. The top surface of the conductive pillars 20p may be substantially aligned with the top surface of the interposers 30.

Referring to FIG. 5C, an encapsulant 40 may be formed on the carrier 510 to encapsulate the electronic components 20 and 20′ and the interposers 30. The encapsulant 40 may be formed by a molding process.

Referring to FIG. 5D, the encapsulant 40 may be grinded to form a planar top surface 401 and to expose ends (top surfaces) of the pins (such as the pin 301) of the interposers 30 and the conductive pillars 20p.

Referring to FIG. 5E, a redistribution layer (RDL) 50 may be formed on the top surface 401 of the encapsulant 40. The RDL 50 includes dielectric layers 50d and conductive layers 50c at least partially covered by the dielectric layers 50d. The conductive pillars 20p and the interposers 30 may be electrically connected to the conductive layers 50c of the RDL 50. In some embodiments, the width of the RDL 50 may be substantially identical to that of the encapsulant 40.

Referring to FIG. 5F, one or more electronic components 60 may be placed on the RDL 50. The electronic components 60 are attached to the RDL 50. The conductive terminals 60p of the electronic components 60 may be connected to the conductive layers 50c of the RDL 50 via the connectors 60c.

Referring to FIG. 5G, a protective element 60u may be formed on the RDL 50 to cover and encapsulate the electronic components 60 and the connectors 60c, and then an encapsulant 70 may be formed on the RDL 50 to cover and encapsulate the electronic components 60, protective element 60u, and the RDL 50. In some embodiments, the width of the encapsulant 70 may be substantially identical to that of the RDL 50.

Referring to FIG. 5H, the carrier 510 may be removed and another carrier 530 may be attached to the encapsulant 70 through an adhesive layer 530h, such that the structure can be upside down to form a circuit structure (i.e., the substrate 10) on the electronic components 20 and 20′ and interposers 30. In some embodiments, the encapsulant 40 may be grinded to form a planar bottom surface 402 and to expose ends (top surfaces) of the pins (such as the pin 301) of the interposers 30. Accordingly, the RDL (i.e., the substrate 10) may be formed on the bottom surface 402.

Referring to FIG. 5I, one or more electrical contacts 80 may be formed on the substrate 10, and the carrier 530 may be removed. The electrical contacts 80 may be connected to the substrate 10. In some embodiments, the electrical contacts 80 may be solder balls. Then, a package structure 1 is formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a circuit structure having a first surface;
a molded interposer disposed on the first surface of the circuit structure, wherein the molded interposer includes a first pin and a second pin, wherein the first pin is tilted in a first direction with respect to the first surface in a cross-sectional view, and wherein the second pin is tilted in a second direction with respect to the first surface in the cross-sectional view, wherein the second direction is different from the first direction.

2. The package structure of claim 1, wherein a first angle of the first pin with respect to the first surface of the circuit structure is different from a second angle of the second pin with respect to the first surface of the circuit structure.

3. The package structure of claim 2, further comprising a first encapsulant encapsulating the molded interposer and having a top surface and a bottom surface opposite to the top surface, wherein a top surface of the first pin is substantially aligned with the top surface of the first encapsulant, and a bottom surface of the first pin is substantially aligned with the bottom surface of the first encapsulant.

4. The package structure of claim 3, wherein the top surface of the first pin is exposed by the top surface of the first encapsulant, and wherein the top surface of the first pin is elliptical in a top view.

5. The package structure of claim 4, wherein a top surface of the second pin is exposed by the top surface of the first encapsulant and elliptical in the top view, and wherein a major axis of the top surface of the first pin extends in a direction different from a major axis of the top surface of the second pin.

6. The package structure of claim 2, wherein a roughness of a top surface of the first pin is substantially identical to a roughness of a bottom surface of the first pin.

7. The package structure of claim 2, wherein the molded interposer includes a third pin tilted in a third direction with respect to the first surface in the cross-sectional view, wherein the third direction is different from the first direction and the second direction.

8. The package structure of claim 3, further an electronic component encapsulated by the first encapsulant and a plurality of conductive pillars disposed on the electronic component, wherein a tilted direction of a first conductive pillar of the plurality of conductive pillars with respect to the top surface of the first encapsulant is substantially identical to a tilted direction of a second conductive pillar of the plurality of conductive pillars with respect to the top surface of the first encapsulant.

9. The package structure of claim 1, wherein the molded interposer includes a second encapsulant encapsulating the first pin and the second pin, wherein a top surface of the second encapsulant is substantially aligned with a top surface of the first pin and the second pin, and a bottom surface of the second encapsulant is substantially aligned with a bottom surface of the first pin and the second pin.

10. The package structure of claim 9, wherein the second encapsulant includes a first filler and a second filler, the first filler having a top surface substantially aligned with the top surface of the second encapsulant, and the second filler having a bottom surface substantially aligned with the bottom surface of the second encapsulant.

11. The package structure of claim 10, wherein the second encapsulant further includes a third filler having a lateral surface substantially aligned with a lateral surface of the second encapsulant.

12. A package structure, comprising:
a first pin encapsulated by a first encapsulant, the first pin having a top surface in an elliptical shape; and
a redistribution layer (RDL) disposed on the first pin, wherein the RDL includes a first conductive via and a dielectric layer partially covering the first conductive via,
wherein the first conductive via is disposed on the first pin and contacts the top surface of the first pin, and wherein the conductive via exposes a portion of the top surface of the first pin.

13. The package structure of claim 12, further comprising a second pin encapsulated by the first encapsulant, wherein the RDL includes a second conductive via disposed on and contacting the top surface of the second pin, wherein a first distance between a left edge of the first pin and a left edge of the first conductive via is different from a second distance between a left edge of the second pin and a left edge of the second conductive via.

14. The package structure of claim 13, wherein a tilted degree of the first pin is greater than a tilted degree of the second pin with regard to a bottom surface of the first encapsulant in a cross-sectional view, and wherein the first distance is greater than the second distance.

15. The package structure of claim 13, wherein the first pin includes an electrical conductive pin and the second pin includes a thermal conductive pin.

16. The package structure of claim 15, wherein the first encapsulant encapsulates the electrical conductive pin and the thermal conductive pin to form an interposer.

17. A package structure, comprising:
a first redistribution layer (RDL) including a first dielectric layer and a first conductive via partially covered by the first dielectric layer;
a second redistribution layer (RDL) including a second dielectric layer and a second conductive via partially covered by the second dielectric layer;
an interposer disposed between the first RDL and the second RDL, the interposer including a first pin; and
an encapsulant encapsulating the interposer and having a top surface and a bottom surface opposite to the top surface,
wherein a top surface of the first pin is substantially aligned with the top surface of the encapsulant, and a bottom surface of the first pin is substantially aligned with the bottom surface of the encapsulant, wherein the first conductive via and the second conductive via taper toward the interposer.

18. The package structure of claim 17, wherein the interposer further comprises a plurality of thermal conductive pins surrounding the first pin, wherein the first pin is an electrical conductive pin.

19. The package structure of claim 17, wherein a center of the first conductive via is misaligned with a center of the first pin in a top view.

20. The package structure of claim 17, wherein the top surface of the first pin is in a polygon in a top view.
